(19) United States
(12) Patent Application Publication
(10) Pub. No.: US 2022/0016835 A1
(43) Pub. Date: Jan. 20, 2022

(54) APPARATUS AND METHOD FOR THE ADDITIVE PRODUCTION OF COMPONENTS

(71) Applicant: FRAUNHOFER-GESELLSCHAFT ZUR FÖRDERUNG DER ANGEWANDTEN FORSCHUNG E.V., München (DE)

(72) Inventors: Thomas NEUBERT, Braunschweig (DE); Michael THOMAS, Braunschweig (DE); Tim Gyung-Min ABRAHAM, Braunschweig (DE); Kristina LACHMANN, Braunschweig (DE)

(73) Assignee: FRAUNHOFER-GESELLSCHAFT ZUR FÖRDERUNG DER ANGEWANDTEN FORSCHUNG E. V., München (DE)

(21) Appl. No.: 17/379,847

(22) Filed: Jul. 19, 2021

(30) Foreign Application Priority Data
Jul. 20, 2020 (DE) 10 2020 209 033.5

(51) Int. Cl. B29C 64/188; B33Y 10/00; B33Y 30/00; B29C 64/118; B29C 64/209

(52) U.S. Cl. CPC B29C 64/188; B33Y 10/00; B29K 2101/12; B29C 64/118; B29C 64/209; B33Y 30/00

(57) ABSTRACT

The present invention relates to an apparatus for the additive production of components. The apparatus comprises an additive production head having an extrusion nozzle and a plasma source arranged around the extrusion nozzle or integrated into the extrusion nozzle for the generation of plasma. The present invention additionally relates to a method for the additive production of components. A plasma is generated in the method with the aid of a plasma source arranged around an extrusion nozzle of an additive production head or integrated into the extrusion nozzle. A material is furthermore melted, pressed through the extrusion nozzle, and deposited in layers. In addition, a treatment by the plasma takes place in which a surface on which the material is deposited in layers is treated with the plasma before the deposition and/or the material is treated with the plasma before, during, and/or after the deposition.

### CROSS-REFERENCE TO A RELATED APPLICATION

This patent application claims the benefit of German Patent Application No. 10 2020 209 033.5, filed on Jul. 20, 2020, the disclosure of which is incorporated herein by reference in its entirety for all purposes.

### BACKGROUND OF THE INVENTION

The present invention relates to an apparatus for the additive production of components. The apparatus comprises an additive production head having an extrusion nozzle and a plasma source arranged around the extrusion nozzle or integrated into the extrusion nozzle for the generation of plasma. The present invention additionally relates to a method for the additive production of components. A plasma is generated in the method with the aid of a plasma source arranged around an extrusion nozzle of an additive production head or integrated into the extrusion nozzle. A material is furthermore melted, pressed through the extrusion nozzle, and deposited in layers. In addition, a treatment by the plasma takes place in which a surface on which the material is deposited in layers is treated with the plasma before the deposition and/or the material is treated with the plasma before, during, and/or after the deposition.

Various additive production methods (fused deposition modeling, laser sintering, stereolithography, binder jetting, among others) represent the current prior art. It is possible with them to produce complex three-dimensional objects from different materials (e.g. polymers, ceramics, metals). The components are built up of individual layers in a computer controlled manner in this process. The high construction degree of freedom, on the one hand, and the low costs with small volumes, on the other hand, are substantive advantages of these techniques. The long production times and the frequently low surface quality (e.g. high roughness) of the printed components are generally disadvantageous in contrast. The surfaces of the components obtained frequently generally also do not yet have the desired properties.

The currently most widely used additive production method is the so-called fused deposition modeling (FDM). In this process, thermoplastic polymers (e.g. PLA, ABS, PC, PET, PP, PEEK, PA, . . . ) are thermally melted, are pressed through an extrusion nozzle, and are then deposited with spatial resolution in a computer controlled manner.

Starting from this, it was the object of the present invention to provide an apparatus and a method for the additive production of components by which components can be produced in a rapid manner that have an increased surface quality and/or improved properties.

This object is achieved by the features of the apparatus described herein for the additive production of components and by the features of the method described herein for the additive production of components, as well as advantageous further developments also described herein.

### BRIEF DESCRIPTION OF THE DRAWING(S)

FIG. 1 depicts a cross-sectional view of an apparatus for additive production of components in accordance with an embodiment of the invention.

FIG. 2 depicts a cross-sectional view of an apparatus for additive production of components in accordance with another embodiment of the invention.

### DETAILED DESCRIPTION OF THE INVENTION

In accordance with the invention, an apparatus for the additive production of components is thus provided that comprises an additive production head having an extrusion nozzle and a plasma source arranged around the extrusion nozzle or integrated into the extrusion nozzle for the generation of plasma.

Various processes can be triggered by the generated plasma that are either advantageous for the 3D printing process (i.e. the additive production) itself (e.g. cleaning of the surface on which the material is deposited with the aid of the extrusion nozzle) or also add new functions to the produced component or improve the properties of the produced component, in particular of the surface of the produced component. The surface quality of the surface of the component can hereby also be increased.

Various modifications to the material to be deposited or deposited in the additive production process can be carried out using the plasma produced by the plasma source, by which modifications the properties of the produced component or the properties of its surface can be improved. It is, for example, possible to clean surfaces of (e.g. organic) contamination. It is additionally possible to oxidize, reduce, and/or roughen surfaces using the produced plasma. It is furthermore possible in the case of polymer surfaces to produce crosslinking by the plasma. It is also possible to produce functional groups on surfaces by the plasma that have a large influence on the surface energy and on the adhesion behavior (improvement of the adhesion of dyes, paints, and adhesives). In addition (thin) films can be produced on surfaces with different functionalities (e.g. hydrophobic, hydrophilic, non-stick, migration barrier layer, etc.) in a so-called plasma-enhanced chemical vapor deposition (PECVD) process through additionally used layer-forming precursors.

Since the plasma source is arranged around the extrusion nozzle or is integrated in the extrusion nozzle, the modification of the material or of the surface by the plasma can take place directly on the additive manufacture of the component so that an in-situ (surface) modification can take place with additively produced components. In this process, the material can be treated with the plasma before, during, and/or after the deposition. Since the plasma treatment takes place directly on the additive production, a time-consuming post-treatment of the produced component by a further apparatus in a separate process can be dispensed with. A comparatively fast manufacture of the additively produced component is achieved in this manner despite the plasma treatment.

An apparatus for the additive production of components is thus provided by the apparatus in accordance with the invention with which components can be manufactured in a comparatively fast manner that have an improved surface quality and/or improved properties.

With the proposed plasma source it is possible to perform cleaning, functionalizing and coating operations. For the deposition of functional coatings, various layer-forming precursors (e.g. hexamethyldisiloxane, tetramethyldisiloxane, hexamethylcyclotrisiloxane, octofluorocyclobutane, aminopropyltrimethoxysilane, aminopropyltriethoxysilane, glycidyloxypropyltrimethoxysilane, mercaptopropyltrimethoxysilane, isocyanatopropyltrimethoxysilane, glycidyl methacrylate, oxazolines, maleic acid anhydride, as well as mixtures thereof) can be fed either directly to the process gas or via a separate line to the coating zone. It is also possible to operate the plasma source with differently pulsed electrical power supply (kHz to MHz range, different duty cycles) in order to deposit the precursors in a structure-preserving manner.

A preferred embodiment of the apparatus in accordance with the invention is characterized in that the plasma source comprises a process gas feed and a high voltage electrode. The production of the plasma can thus take place in a simple manner within the apparatus in that a process gas supplied through the process gas feed is ionized by an electrical field produced by the high voltage electrode. The plasma source can preferably be suitable to produce the plasma by a gas discharge that is preferably selected from the group consisting of dielectrically hindered discharges, corona discharges, arc discharges, by discharges excited by microwaves, by discharges excited by radio frequency, and combinations thereof.

In accordance with a further preferred embodiment, the plasma source is arranged around the extrusion nozzle and comprises a depression arranged on an (outer) surface of the plasma source and connected to the process gas feed as a plasma production region, with the depression and the high voltage electrode being arranged around the extrusion nozzle and concentrically with one another. The process gas can first be conducted via the process gas feed into the depression in this arrangement, with the plasma then being produced in the depression with the aid of the high voltage electrode. The plasma produced in the depression can subsequently come into contact with the surface on which the material is deposited in layers or with the material itself. It can consequently be achieved in a simple manner by the arrangement of the depression on a surface of the plasma source around the extrusion nozzle and concentrically with the high voltage electrode that the plasma is produced in the vicinity of the material deposited by the extrusion nozzle or of the surface on which the material is to be deposited and can then come without difficulty into contact with the material deposited by the extrusion nozzle or with the surface on which the material is to be deposited. It can additionally be achieved by the arrangement that the plasma is distributed uniformly in the region around the extrusion nozzle so that the freshly deposited material very quickly comes into contact with the plasma (independently of the direction of movement of the extrusion nozzle).

It is particularly advantageous with this arrangement that the depression can border a region at which the material is or was deposited by the extrusion nozzle. A supply of the plasma to the material freshly deposited by the extrusion nozzle and/or to the surface on which the material is to be deposited can thus be achieved in a simple manner so that a problem-free modification of the deposited material or of its surface and/or of the surface on which the material is to be deposited is made possible by the plasma.

The depression connected to the process gas feed can be a recess within an outer surface of the plasma source. The (outer) surface of the plasma source on which the depression is arranged can face in the same direction as the opening of the extrusion nozzle through which the material to be deposited exits the extrusion nozzle. The depression connected to the process gas feed is preferably circularly arranged around the extrusion nozzle. The depression connected to the process gas feed is preferably circularly arranged around the extrusion nozzle such that the extrusion nozzle is at the center.

The plasma source can contact the extrusion nozzle. The plasma source can be cylindrically arranged around the extrusion nozzle, can preferably cylindrically abut around the extrusion nozzle.

A plasma production region in the sense of the present invention can be understood as the region in which plasma is or can be produced (e.g. with the aid of the process gas and the high voltage electrode).

A further preferred embodiment is characterized in that the plasma source is integrated into the extrusion nozzle, with the process gas feed being connected to a passage of the extrusion nozzle for pressing through melted material, with the high voltage electrode being arranged around a plasma production region of the passage of the extrusion nozzle and with the connection between the process gas feed and the passage of the extrusion nozzle being located in the plasma production region and/or in the pressing direction of the material before the plasma production region. In this arrangement, the process gas can first be supplied via the process gas feed to the material present in the extrusion nozzle and the plasma can subsequently be produced within the extrusion nozzle with the aid of the high voltage electrode. The plasma can thus come into contact with the not yet deposited material still in the extrusion nozzle. The plasma can additionally escape from the extrusion nozzle with the material and can then also come into contact with the already deposited material. A modification of the material by the plasma is thus made possible in a simple manner. It can thus be achieved in a simple manner by this special embodiment that the plasma is produced in the direct vicinity of the material and can therefore come into contact without difficulty with the material to be deposited or deposited by the extrusion nozzle or with the surface on which the material is to be deposited. It can additionally be achieved by this arrangement that the plasma is distributed uniformly in the region around the extrusion nozzle so that the freshly deposited material very quickly comes into contact with the plasma (independently of the direction of movement of the extrusion nozzle).

A further preferred embodiment of the apparatus in accordance with the invention is characterized in that the plasma source comprises a precursor gas feed, with the precursor gas feed preferably being connected to a depression that is arranged on an (outer) surface of the plasma source and that is arranged around the extrusion nozzle. The (outer) surface of the plasma source on which the depression is arranged can face in the same direction as the opening of the extrusion nozzle through which the material to be deposited exits the extrusion nozzle. The depression connected to the precursor gas feed is preferably circularly arranged around the extrusion nozzle. The depression connected to the precursor gas feed is preferably circularly arranged around the extrusion nozzle such that the extrusion nozzle is at the center.

The depression connected to the precursor gas feed is preferably not the depression connected to the process gas feed. Alternatively, the depression connected to the precursor gas feed can, however, be the depression connected to the process gas feed. The depression connected to the precursor gas feed is preferably arranged on the same (outer) surface of the plasma source as the depression connected to the process gas feed. The depression connected to the precursor gas feed preferably has a smaller distance from the extrusion nozzle than the depression connected to the process gas feed. The depression connected to the precursor gas feed and/or the depression connected to the process gas feed is/are preferably circularly arranged around the extrusion nozzle. The depression connected to the precursor gas feed and/or the depression connected to the process gas feed is/are preferably circularly arranged around the extrusion nozzle such that the extrusion nozzle is at the center.

A particularly preferred embodiment of the apparatus in accordance with the invention is characterized in that the plasma source is arranged around the extrusion nozzle and comprises a first depression arranged on an (outer) surface of the plasma source and connected to the process gas feed as the plasma production region, with the first depression and the high voltage electrode being arranged around the extrusion nozzle and concentrically with one another, with the plasma source comprising a precursor gas feed, and with the precursor gas feed being connected to a second depression that is arranged on the (outer) surface of the plasma source and that is arranged around the extrusion nozzle. The (outer) surface of the plasma source on which the first depression and the second depression are arranged can face in the same direction as the opening of the extrusion nozzle through which the material to be deposited exits the extrusion nozzle. The second depression preferably has a smaller distance from the extrusion nozzle than the first depression. The first depression and/or the second depression is/are preferably circularly arranged around the extrusion nozzle. The first depression and/or the second depression is/are preferably circularly arranged around the extrusion nozzle such that the extrusion nozzle is at the center.

The apparatus preferably comprises a heating block for the melting of the material from which the components are to be produced.

The apparatus in accordance with the invention can additionally comprise a grounded electrode and/or a high voltage generator. The grounded electrode is preferably arranged around the extrusion nozzle and/or concentrically to the high voltage electrode.

The high voltage electrode and/or the grounded electrode is/are preferably electrically insulated.

The high voltage electrode and the grounded electrode are preferably suitable for an electrical (alternating) field having a potential difference >1 kV (or >1 kHz) to be able to be produced.

The high voltage electrode and/or the grounded electrode is/are preferably a circular electrode or circular electrodes.

The apparatus in accordance with the invention can be a 3D printer, preferably an FDM 3D printer.

The plasma source and/or the extrusion nozzle preferably comprises/comprise a base body that consists of a temperature-stable and electrically non-conductive material, particularly preferably a ceramic material or glass.

A method for the additive production of components is also provided in accordance with the invention in which
a) a plasma is generated with the aid of a plasma source arranged around an extrusion nozzle of an additive production head or integrated into the extrusion nozzle;
b) a material is melted, pressed through the extrusion nozzle, and deposited in layers; and
c) a treatment with the plasma takes place in which
   a surface on which the material is deposited in layers in step b) is treated with the plasma before the deposition in step b); and/or
   the material is treated with the plasma before, during, and/or after the deposition in step b).

A plasma is produced with the aid of a plasma source in step a). The plasma source is arranged around an extrusion nozzle of an additive production head or is integrated into the extrusion nozzle.

In step b), a material from which the desired component is to be produced is first melted, is then pressed through the extrusion nozzle, and is finally deposited in layers. Step b) can be performed before, during, and/or after step a). The melting of the material can take place with the aid of a heating block, for example.

A treatment with the plasma takes place in step c). In a first variant of the treatment with the plasma, a surface on which the material is deposited in layers in step b) is treated with the plasma before the deposition in step b). The surface can be cleaned before the deposition here, for example. Contaminants on the surface of the produced component can hereby be reduced or avoided, whereby the surface quality and/or the (surface) properties of the component is/are improved. In a second variant of the treatment with the plasma, the material is treated with the plasma before, during and/or after the deposition in step b). The material or its surface can hereby be modified (e.g. by oxidation, reduction, cleaning, roughening, and/or crosslinking), whereby the surface quality and/or the (surface) properties of the component can be improved. In a third variant of the treatment with the plasma, a surface on which the material is deposited in layers in step b) is treated with the plasma before the deposition in step b) and the material is treated with the plasma before, during, and/or after the deposition in step b).

A preferred variant of the method in accordance with the invention is characterized in that the plasma is produced by a gas discharge in step a) that is preferably selected from the group consisting of dielectrically hindered discharges, corona discharges, arc discharges, discharges excited by microwaves, discharges excited by radio frequency, and combinations thereof.

In accordance with a further preferred variant, the plasma source has a process gas feed and a high voltage electrode, with a process gas supplied by the process gas feed being ionized by an electrical field produced by the high voltage electrode to produce the plasma in step a). A particularly simple production of the plasma within the apparatus is possible in this manner.

A further preferred variant of the method in accordance with the invention is characterized in that
the plasma source is arranged around the extrusion nozzle, with the process gas first being conducted via the process gas feed into a plasma production region of the plasma source within which the plasma is produced, and with the plasma subsequently coming into contact with the surface on which the material is deposited in layers in step b) and/or with the material, with the plasma production region preferably being a depression arranged on an (outer) surface of the plasma source and around the extrusion nozzle; or
the plasma source is integrated into the extrusion nozzle, with the process gas first being supplied via the process gas feed to the material present in the extrusion nozzle and with the plasma subsequently being produced within the extrusion nozzle, with the plasma preferably
   coming into contact with the material present in the extrusion nozzle; and/or
   escaping through an outlet of the extrusion nozzle and coming into contact with the already deposited material.

In accordance with a further preferred variant, the process gas is selected from the group consisting of
argon, helium, oxygen, nitrogen, hydrogen, carbon dioxide, air, water vapor, and mixtures thereof;
mixtures of argon and one or more substances selected from the group comprising hexamethyldisiloxane, tetramethyldisiloxane, hexamethylcyclotrisiloxane, octofluorocyclobutane, and mixtures thereof;
mixtures of argon, hydrogen, and a metal salt aerosol, with the metal salt preferably being selected from the group consisting of gold chloride, silver chloride, copper chloride, and mixtures thereof; and
mixtures thereof.

Different effects, in particular different modifications of the material or of the produced component or of its surface, can be achieved by the use of different process gases. A cleaning of the surface on which the material is to be deposited from organic contaminants (e.g. adhesive residues, adhesion promoters, polymer residues) can, for example, be achieved by the use of a process gas containing oxygen (e.g. argon with oxygen) in that the reactive oxygen species present in the plasma remove them by oxidative processes. It is also possible to produce functional groups on surfaces by a use of reactive process gases that have a large influence on the surface energy and on the adhesion behavior (improvement of the adhesion of dyes, paints, and adhesives). The adhesion of the individual deposited layers (e.g. polymer layers) with respect to one another and thus the mechanical stability of the total produced component (in the z direction) can furthermore be improved, for example by a use of argon with oxygen or nitrogen/air. A deposition of hydrophobic layers (during and/or after the printing process) can take place by a use of mixtures of argon and one or more substances selected from the group consisting of hexamethyldisiloxane, tetramethyldisiloxane, hexamethylcyclotrisiloxane, octofluorocyclobutane, and mixtures thereof. Mixtures of argon, hydrogen, and a metal salt aerosol (e.g. gold chloride, silver chloride, copper chloride) can furthermore be used to produce metallic layers (during and/or after the printing process).

A further preferred variant of the method in accordance with the invention is characterized in that the material (that is melted in step b)) is selected from the group consisting of polymers, ceramic materials, metals, and mixtures and combinations thereof. The polymers can, for example, be thermoplastic polymers that are preferably selected from the group consisting of polylactides (PLA), acrylonitrile butadiene styrene copolymers (ABS), polycarbonates (PC), polyethylene terephthalate (PET), polypropylene (PP), polyetheretherketone (PEEK), polyamides (PA), and mixtures thereof.

In accordance with a further preferred variant of the method in accordance with the invention, the material or at least one surface of the deposited material is modified by the plasma treatment, with the modification preferably being selected from the group consisting of a production of functional groups on at least one surface of the deposited material, an at least partial crosslinking of the material, an at least partial oxidation of the material, an at least partial reduction of the material, an at least partial roughening of a surface of the deposited material, an at least partial cleaning of the surface of the deposited material, and combinations thereof. The different modifications can be implemented, for example, by the use of suitable process gases. A crosslinking in the case of the use of a polymer material is possible, for example, by shortwave UV radiation from the gas discharge.

A further preferred variant of the method in accordance with the invention is characterized in that at least one precursor gas is supplied to the process gas and/or to the generated plasma, by which precursor gas at least one layer is deposited on a surface on which the melted material is deposited in layers in step b) and/or on at least one surface of the deposited material, with the deposition preferably taking place by means of plasmaenhanced chemical vapor deposition. Specific layers, e.g. adhesion promoter layers, can be deposited on the surface of the produced components by the use of precursor gases.

The at least one precursor gas preferably comprises a precursor that is selected from the group consisting of aminopropyltrimethoxysilane, aminopropyltriethoxysilane, glycidyloxypropyltrimethoxysilane, mercaptopropyltrimethoxysilane, isocyanatopropyltrimethoxysilane, glycidylmethacrylate, oxazolines, maleic acid anhydride, and mixtures thereof. These precursors are very well-suited for the deposition of adhesion promoter layers.

The at least one layer is preferably selected from the group consisting of adhesion promoter layers, dispersion layers, migration barrier layers, hydrophobic layers, hydrophilic layers, and mixtures and combinations thereof. The deposition of dispersion layers (different particles embedded in a polymer matrix) is, for example, possible for the implementation of different functions: self-healing layers, reversible adhesion, tribologically active microparticles (hBN, PTFE), particles absorbing infrared radiation for the thermal post-treatment of polymer surfaces.

In accordance with a further preferred variant of the method in accordance with the invention, the method is carried out using an apparatus in accordance with the invention.

The following treatment effects are, for example, possible by different process management and process gases:
1. cleaning of the press bed from organic contaminants (adhesive residues, adhesion promoters, polymer residues) before the printing process by a plasma containing oxygen (e.g. argon with oxygen as process gases);
2. production of adhesion promoter layers on the press bed before the printing process (e.g. argon with an admixed adhesion-promoting precursor such as aminopropyltrimethoxysilane, aminopropyltriethoxysilane, glycidyloxypropyltrimethoxysilane, mercaptopropyltrimethoxysilane, isocyanatopropyltrimethoxysilane, glycidylmethacrylate, oxazolines, maleic acid anhydride);
3. production of adhesion promoter layers between different polymers adhering weakly to one another on the printing of multipart components (e.g. argon with an admixed adhesion-promoting precursor such as aminopropyltrimethoxysilane, aminopropyltriethoxysilane, glycidyloxypropyltrimethoxysilane, mercaptopropyltrimethoxysilane, isocyanatopropyltrimethoxysilane, glycidylmethacrylate, oxazolines, maleic acid anhydride);
4. production of adhesion promoter layers on a fully printed component for subsequent adhesion, painting, or color printing processes (e.g. argon with admixed adhesion promoting precursors such as aminopropyltrimethoxysilane, aminopropyltriethoxysilane, glycidyloxypropyltrimethoxysilane, mercaptopropyltrimethoxysilane, isocyanatopropyltrimethoxysilane, glycidylmethacrylate, oxazolines, maleic acid anhydride) in a PECVD process;
5. production of adhesion promoter layers on metallic or ceramic surfaces for improving the bonding force of subsequently printed polymers;
6. improvement of the mechanical stability of a 3D printed component in the z direction by an improvement of the adhesion of the polymer layers by a plasma treatment during the 3D printing of a polymer (process gas: argon with oxygen or nitrogen/air);
7. deposition of hydrophobic layers during and after completion of the 3D printing process (process gas: e.g. argon with hexamethyldisiloxane, tetramethyl-disiloxane, hexamethylcyclotrisiloxane, octofluorocyclobutane);
8. deposition of metallic layers during and after completion of the 3D printing process (process gas: argon with hydrogen and a metal salt aerosol (for example gold chloride, silver chloride or copper chloride));
9. deposition of dispersion layers (different particles embedded in a polymer matrix) for the implementation of different functions: self-healing layers, reversible adhesion, tribologically active microparticles (hBN, PTFE), particles absorbing infrared radiation for the thermal post-treatment of polymer surfaces.

The present invention will be explained in more detail with reference to the following Figures and examples without restricting the invention to the specifically shown parameters.

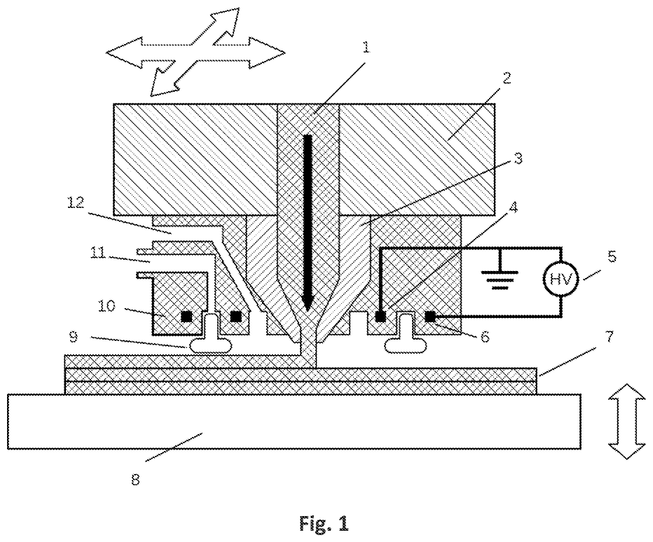

A cross-sectional representation of an exemplary embodiment of the apparatus in accordance with the invention for the additive production of components is shown in FIG. 1. The apparatus comprises an additive production head having an extrusion nozzle 3 and a plasma source 10 arranged around the extrusion nozzle 3 for the generation of plasma 9. The apparatus further comprises a heating block 2 for the melting of the material 1, a process gas feed 11, a high voltage electrode 6, a grounded electrode 4, and a high voltage generator 5. The high voltage electrode 6 and the grounded electrode 4 are circular electrodes between which a high electrical alternating field (potential difference >1 kV, >1 kHz) is produced. The plasma source 10 comprises a first depression arranged on an outer surface of the plasma source 10 and connected to the process gas feed 11 as the plasma production region, with the first depression and the high voltage electrode 6 being arranged around the extrusion nozzle 3 and concentrically with one another. The outer surface of the plasma source 10 on which the first depression is arranged faces in the same direction as the opening of the extrusion nozzle 3 through which the material 1 to be deposited exits the extrusion nozzle. The plasma source 10 further comprises a precursor gas feed 12, with the precursor gas feed 12 being connected to a second depression that is arranged around the extrusion nozzle 3. The second depression is arranged on the same outer surface of the plasma source 10 as the first depression. The first and second depressions are arranged concentrically with one another. The second depression additionally has a smaller distance from the extrusion nozzle than the first depression. The first depression and the second depression are circularly arranged around the extrusion nozzle such that the extrusion nozzle is at the center.

An exemplary variant of the method in accordance with the invention is additionally shown in FIG. 1. Here, the material 1, e.g. a polymer filament, is melted with the aid of the heating block 2, is pressed through the extrusion nozzle 3, and is deposited in layers on a press bed 8. A process gas is conducted via the process gas feed 11 into the plasma production region or the first depression. The process gas is there ionized by an electrical field produced by the high voltage electrode 6 or by a gas discharge, whereby the plasma 9 is produced. The plasma 9 escapes from the depression and comes into contact with the material 7 already deposited such that the deposited material 7 or its surface can be modified by the plasma. A precursor gas can additionally be supplied via the precursor gas feed 12, is conducted into the second depression, and can escape from there and come into contact with the plasma and the already deposited material 7. A special coating can be obtained on the deposited material 7 or on its surface in this manner in dependence on the precursor gas used.

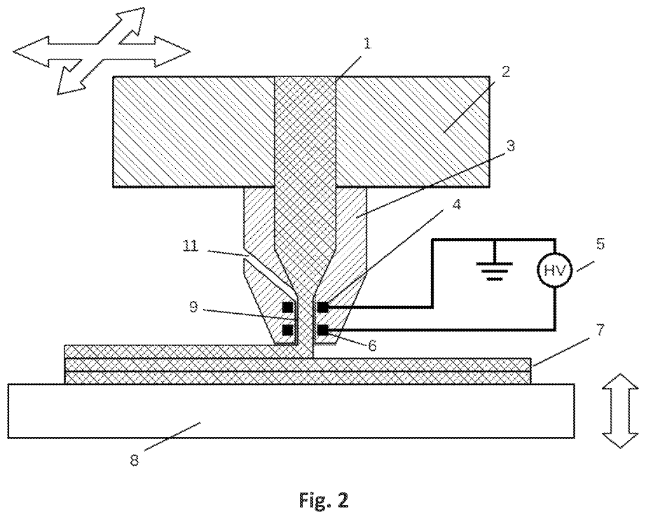

A cross-sectional representation of a further exemplary embodiment of the apparatus in accordance with the invention for the additive production of components is shown in FIG. 2. The apparatus likewise comprises an additive production head having an extrusion nozzle 3. Unlike the embodiment shown in FIG. 1, the plasma source for producing the plasma is here integrated into the extrusion nozzle 3, however. The apparatus further comprises a heating block 2 for the melting of the material 1, a process gas feed 11, a high voltage electrode 6, a grounded electrode 4, and a high voltage generator 5. The high voltage electrode 6 and the grounded electrode 4 are circular electrodes between which a high electrical alternating field (potential difference >1 kV, >1 kHz) is produced. The process gas feed 11 is connected to a passage of the extrusion nozzle 3 for pressing through the melted material 1 to be deposited. This passage has a plasma production region around which the high voltage electrode 6 is arranged. The connection between the process gas feed 11 and the passage of the extrusion nozzle 3 is here located just in front of the plasma production region (in the pressing direction of the material).

An exemplary variant of the method in accordance with the invention is also shown in FIG. 2. Analogously to the variant described in FIG. 1, the material 1, e.g. a polymer filament, is melted with the aid of the heating block 2, is pressed through the extrusion nozzle 3, and is deposited in layers on a press bed 8. Unlike the variant in FIG. 1, however, the process gas supplied via the process gas feed 11 is here conducted into the passage of the extrusion nozzle 3 where it moves into the plasma production region present there. The process gas is there ionized by an electrical field produced by the high voltage electrode 6 or by a gas discharge, whereby the plasma 9 is produced. It then comes directly into contact with the not yet deposited material 1. The plasma 9 can additionally escape from the outlet of the extrusion nozzle, and there also comes into contact with the already deposited material 7. The deposited material 7 or its surface can be modified by the plasma in this manner.

1-16. (canceled)

17. An apparatus for additive production of components comprising an additive production head having an extrusion nozzle and a plasma source arranged around the extrusion nozzle or integrated into the extrusion nozzle for generating plasma.

18. The apparatus of claim 17, wherein the plasma source comprises a process gas feed and a high voltage electrode.

19. The apparatus of claim 17, wherein the plasma source is arranged around the extrusion nozzle and comprises a depression arranged on a surface of the plasma source and connected to the process gas feed as a plasma production region, with the depression and the high voltage electrode are arranged around the extrusion nozzle and concentrically with one another.

20. The apparatus of claim 17, wherein the plasma source is integrated into the extrusion nozzle, wherein the process gas feed is connected to a passage of the extrusion nozzle for pressing through melted material, wherein the high voltage electrode is arranged around a plasma production region of the passage of the extrusion nozzle and wherein the connection between the process gas feed and the passage of the extrusion nozzle is located in the plasma production region and/or in the pressing direction of the material before the plasma production region.

21. The apparatus of claim 17, wherein the plasma source comprises a precursor gas feed.

22. The apparatus of claim 21, wherein the precursor gas feed is connected to a depression that is arranged on a surface of the plasma source and that is arranged around the extrusion nozzle.

23. A method for additive production of components in which
(a) a plasma is generated with the aid of a plasma source arranged around an extrusion nozzle of an additive production head or integrated into the extrusion nozzle;
(b) a material is melted, pressed through the extrusion nozzle, and deposited in layers; and
(c) a treatment with the plasma takes place in which
a surface on which the material is deposited in layers in step (b) is treated with the plasma before the deposition in step (b); and/or
the material is treated with the plasma before, during, and/or after the deposition in step (b).

24. The method of claim 23, wherein the plasma is produced by a gas discharge in step (a) that is selected from the group consisting of dielectrically hindered discharges, corona discharges, arc discharges, discharges excited by microwaves, discharges excited by radio frequency, and combinations thereof.

25. The method of claim 23, wherein the plasma source has a process gas feed and a high voltage electrode, wherein the process gas supplied by the process gas feed is ionized by an electrical field produced by the high voltage electrode to produce the plasma in step (a).

26. The method of claim 25, wherein:
the plasma source is arranged around the extrusion nozzle, wherein the process gas is first conducted via the process gas feed into a plasma production region of the plasma source within which the plasma is produced, and with the plasma subsequently coming into contact with the surface on which the material is deposited in layers in step (b) and/or with the material; or
the plasma source is integrated into the extrusion nozzle, with the process gas first being supplied via the process gas feed to the material present in the extrusion nozzle and with the plasma subsequently being produced within the extrusion nozzle.

27. The method of claim 23, wherein the process gas is selected from the group consisting of
argon, helium, oxygen, nitrogen, hydrogen, carbon dioxide, air, water vapor, and mixtures thereof,
mixtures of argon and one or more substances selected from the group consisting of hexamethyldisiloxane, tetramethyldisiloxane, hexamethylcyclotrisiloxane, and octofluorocyclobutane;
mixtures of argon, hydrogen, and a metal salt aerosol; and
mixtures thereof.

28. The method of claim 23, wherein the material is selected from the group consisting of polymers, ceramic materials, metals, and mixtures and combinations thereof.

29. The method of claim 23, wherein the material or at least one surface of the deposited material is modified by the treatment of the plasma.

30. The method of claim 29, wherein the modification is selected from the group consisting of a production of functional groups on at least one surface of the deposited material, an at least partial crosslinking of the material, an at least partial oxidation of the material, an at least partial reduction of the material, an at least partial roughening of a surface of the deposited material, an at least partial cleaning of the surface of the deposited material, and combinations thereof.

31. The method of claim 23, wherein at least one precursor gas is supplied to the process gas and/or to the generated plasma, by which precursor gas at least one layer is deposited on a surface on which the melted material is deposited in layers in step (b) and/or on at least one surface of the deposited material.

32. The method of claim 23, wherein the at least one precursor gas comprises a precursor that is selected from the group consisting of aminopropyltrimethoxysilane, aminopropyltriethoxysilane, glycidyloxypropyltrimethoxysilane, mercaptopropyltrimethoxysilane, isocyanatopropyltrimethoxysilane, glycidylmethacrylate, oxazolines, maleic acid anhydride, and mixtures thereof.

33. The method of claim 31, wherein the at least one layer is selected from the group consisting of adhesion promoter layers, dispersion layers, migration barrier layers, hydrophobic layers, hydrophilic layers, and mixtures and combinations thereof.

34. The method of claim 23, which is carried out by utilizing an apparatus comprising an additive production head having an extrusion nozzle and a plasma source arranged around the extrusion nozzle or integrated into the extrusion nozzle for generating plasma.
